(19) United States
(12) Patent Application Publication
(10) Pub. No.: US 2014/0001623 A1
(43) Pub. Date: Jan. 2, 2014

(54) MICROELECTRONIC STRUCTURE HAVING A MICROELECTRONIC DEVICE DISPOSED BETWEEN AN INTERPOSER AND A SUBSTRATE

(71) Applicant: PRAMOD MALATKAR, Chandler, AZ (US)

(72) Inventor: PRAMOD MALATKAR, Chandler, AZ (US)

(21) Appl. No.: 13/535,905

(22) Filed: Jun. 28, 2012

(51) Int. Cl. H01L 23/48; H01L 21/60; H01L 25/04; H01L 23/498

(52) U.S. Cl. 257/690; 257/774; 257/738; 438/126; 257/E23.01; 257/E25.003; 257/E23.069; 257/E21.509

(57) ABSTRACT

A microelectronic structure comprising a microelectronic package that includes at least one microelectronic device attached to a microelectronic interposer, wherein the microelectronic package is mounted to a microelectronic substrate, such that the microelectronic device is disposed between and in electrical communication with both the microelectronic interposer and the microelectronic substrate.

### TECHNICAL FIELD

Embodiments of the present description generally relate to the field of microelectronic structures and, more particularly, to a microelectronic structure including a microelectronic package comprising a microelectronic device attached to an interposer, wherein the microelectronic package is mounted to a microelectronic substrate, such that the microelectronic device is disposed between and in electrical communication with the microelectronic interposer and the microelectronic substrate.

### BACKGROUND ART

The microelectronic industry is continually striving to produced ever faster and smaller microelectronic structures for use in various mobile electronic products, such as portable computers, electronic tablets, cellular phones, digital cameras, and the like. Typically, a microelectronic device, such a microprocessor, a chipset, a graphics device, a wireless device, a memory device, an application specific integrated circuit, or the like, is attached to a microelectronic interposer, which may also have other microelectronic components, such as resistor, capacitors, and inductors, attached thereto. The interposer is, in turn, attached to a microelectronic substrate, which enables electrical communication between the microelectronic device, the microelectronic components, and external devices. However, the electrical interconnect routes in such structures can be relatively long, which may result in a high resistance and inductance, and thus, reduced performance of the microelectronic structure.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a side cross-sectional view of a microelectronic structure having a microelectronic package mounted on a microelectronic substrate, as known in the art.

FIG. 2 illustrates a side cross-sectional view of a microelectronic structure having a microelectronic device attached between a microelectronic interposer and a microelectronic substrate, according to an embodiment of the present description.

FIG. 3 illustrates a side cross-sectional view of an inset A of FIG. 2, wherein the microelectronic device is attached between the microelectronic interposer and the microelectronic substrate with solder grid arrays, according to an embodiment of the present description.

FIG. 4 illustrates a side cross-sectional view of the inset A of FIG. 2, wherein the microelectronic device is attached between the microelectronic interposer and the microelectronic substrate with solder grid arrays, according to another embodiment of the present description.

FIG. 5 illustrates a side cross-sectional view of the inset A of FIG. 2, wherein the microelectronic device is attached between the microelectronic interposer and the microelectronic substrate with ball grid arrays, according to one embodiment of the present description.

FIG. 6 illustrates a side cross-sectional view of a microelectronic structure having a plurality of microelectronic devices, according to another embodiment of the present description.

FIG. 7 illustrates a flow diagram of a process for fabrication a microelectronic structure, according to an embodiment of the present description.

FIG. 8 illustrates an electronic system/device, according to one implementation of the present description.

### DESCRIPTION OF THE EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description may include a microelectronic structure having a microelectronic package comprising at least one microelectronic device attached to an interposer, wherein the microelectronic package is mounted to a microelectronic substrate, such that the microelectronic device is disposed between and in electrical communication with both the microelectronic interposer and the microelectronic substrate. The various embodiments of the present description position the microelectronic device closer to the microelectronic substrate, which may improve power delivery and achieve higher input/output speeds. The various embodiments of the present description may also have the advantage of a lower Z-profile (i.e. microelectronic structure height) and may result in improved surface mount yields (e.g. lower risk of non-wets, solder bridging, and microelectronic structure warpage), as will be understood to those skilled in the art.

In the production of microelectronic structures, microelectronic packages are generally mounted on microelectronic substrates that provide electrical communication routes between the microelectronic packages and external components. As shown in FIG. 1, a microelectronic device 102, such as a microprocessor, a chipset, a controller, a graphics device, a wireless device, a memory device, an application specific integrated circuit, or the like, may be attached to a microelectronic interposer 104 through a plurality of interconnects 106, to form a microelectronic package 120. The device-to-interposer interconnects 106 may extend between bond pads 108 on an active surface 112 of the microelectronic device 102 and substantially mirror-image bond pads 114 on a die side surface 116 of the microelectronic interposer 104. The microelectronic device bond pads 108 may be in electrical communication with integrated circuitry (not shown) within the microelectronic device 102. The microelectronic interposer bond pads 114 may be in electrical communication with conductive routes (shown as dashed lines 118) within the microelectronic interposer 104. The microelectronic interposer conductive routes 118 may provide electrical communication routes to bond pads 122 on a land side surface 124 of the microelectronic interposer 104.

The microelectronic interposer 104 and its respective microelectronic interposer conductive routes 118 may be made of multiple layers of conductive traces, such as copper or aluminum, built up on and through dielectric layers, such as epoxy, which are laminated on either side of the matrix core, such as fiberglass or epoxy. Furthermore, land side passive devices 126, such as resistors, capacitors, and inductors, may be attached to the microelectronic interposer land side surface 124, and wherein the land side passive device 126 may be in electrical communication with the microelectronic device 102 through respective microelectronic interposer conductive routes 118. Moreover, die side passive devices 128, such as resistors, capacitors, and inductors, may be attached to the microelectronic interposer die side surface 116, and wherein the die side passive devices 128 may be in electrical communication with the microelectronic device 102 through respective microelectronic interposer conductive routes 118.

As further shown in FIG. 1, the microelectronic package 120 may be mounted on a microelectronic substrate 130, which may provide electrical communication routes between the microelectronic package 120 and external components (not shown). The microelectronic package 120 may be attached to the microelectronic substrate 130 through a plurality of interconnects 132, to form a microelectronic structure 100. The interposer-to-substrate interconnects 132 may extend between the microelectronic interposer land side bond pads 122 and substantially mirror-image bond pads 134 on a first surface 136 of the microelectronic substrate 130. The microelectronic substrate first surface bond pads 134 may be in electrical communication with conductive routes (shown as dashed lines 138) on or within the microelectronic substrate 130. The microelectronic substrate conductive routes 138 may provide electrical communication routes to external components (not shown).

As it may be seen from FIG. 1, the arrangement of components in the microelectronic structure 100 may result in relatively long conductive routes between its components, which may result in higher interconnect resistance and inductance that may limit the current carrying capacity and attainable input/output speeds, as will be understood to those skilled in the art.

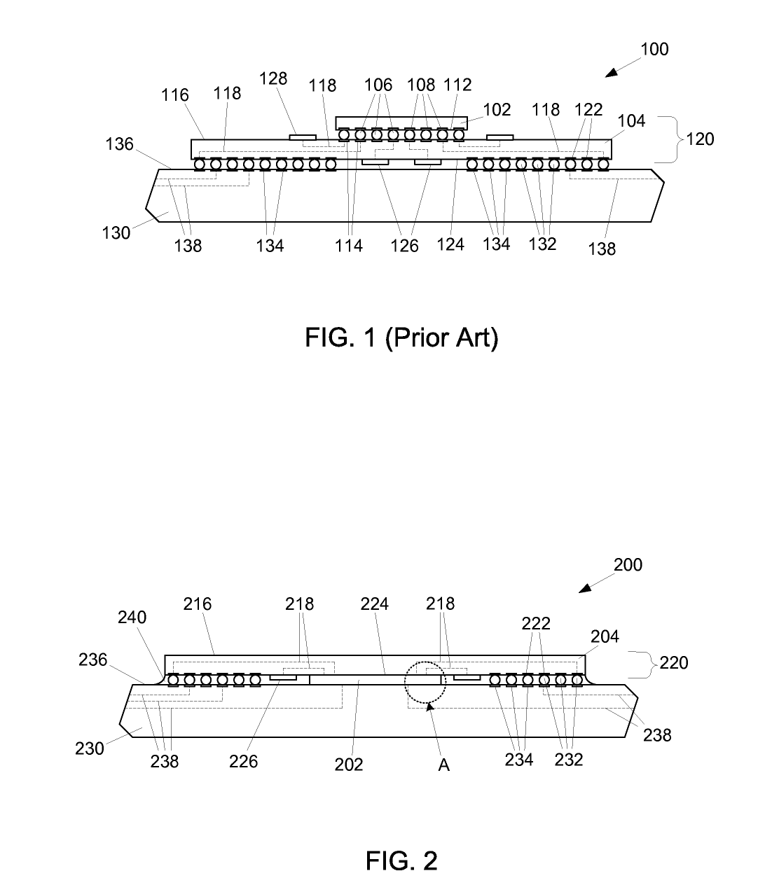

In one embodiment as shown in FIG. 2, a microelectronic device 202, such as a microprocessor, a chipset, a controller, a graphics device, a wireless device, a memory device, an application specific integrated circuit, or the like, may be attached to a land side surface 224 of a microelectronic interposer 204 to form a microelectronic package 220. The microelectronic device 202 may be in electrical communication with conductive routes (shown as dashed lines 218) within the microelectronic interposer 204. The microelectronic interposer conductive routes 218 may provide electrical communication routes to bond pads 222 on the microelectronic interposer land side surface 224. The microelectronic interposer 204 and its respective microelectronic interposer conductive routes 218 may be made of multiple layers of conductive traces, such as copper or aluminum, built up on and through dielectric layers, such as epoxy, which are laminated on either side of the matrix core, such as fiberglass or epoxy, may be formed a coreless interposer, or may be formed as a bumpless build-up layer structure with an embedded microelectronic device, as will be understood to those skilled in the art.

As further shown in FIG. 2, the microelectronic package 220 may be mounted on a microelectronic substrate 230, which may provide electrical communication routes between the microelectronic package 220 and external components (not shown). The microelectronic interposer 204 may be electrically attached to the microelectronic substrate 230 through a plurality of interconnects 232, and the microelectronic device 202 may also be electrically attached to the microelectronic substrate 230 to form a microelectronic structure 200. The interposer-to-substrate interconnects 232 may extend between the microelectronic interposer land side surface bond pads 222 and substantially mirror-image bond pads 234 on a first surface 236 of the microelectronic substrate 230. The microelectronic substrate first surface bond pads 234 may be in electrical communication with conductive routes (shown as dashed lines 238) on or within the microelectronic substrate 230. The microelectronic device 202 may also be in electrical communication with the microelectronic substrate conductive routes 238, as will be subsequently discussed. The microelectronic substrate conductive routes 238 provide electrical communication routes to external components (not shown). Furthermore, land side passive devices 226, such as resistors, capacitors, and inductors, may be attached to the microelectronic interposer land side surface 224 and in electrical communication with the microelectronic device 202 through respective microelectronic interposer conductive routes 218.

As still further shown in FIG. 2, an electrically-insulating flowable material, such as an underfill material 240, may be disposed between the microelectronic interposer 204 and the microelectronic substrate 230, which substantially encapsulates the interposer-to-substrate interconnects 232, the microelectronic device 202, and the land side passive devices 226, if present. The underfill material 240 may be used to reduce mechanical stress issues that can arise from thermal expansion mismatch and protect component from contamination. The underfill material 240 may be an epoxy material, including, but not limited to epoxy, cyanoester, silicone, siloxane and phenolic based resins, that has sufficiently low viscosity to be wicked between the microelectronic interposer 204 and the microelectronic substrate 230.

The microelectronic substrate 230 may be any appropriate substrate, such as a motherboard, a printed circuit board, and the like, and may be primarily composed of any appropriate material, including, but not limited to, bismaleimine triazine resin, fire retardant grade 4 material, polyimide materials, glass reinforced epoxy matrix material, and the like, as well as laminates or multiple layers thereof. The microelectronic substrate conductive routes 238 may be composed of any conductive material, including but not limited to metals, such as copper and aluminum, and alloys thereof. As will be understood to those skilled in the art, the microelectronic substrate conductive routes 238 may be formed as a plurality of conductive traces (not shown) formed on layers of dielectric material (constituting the layers of the microelectronic substrate material), which are connected by conductive vias (not shown).

Although the embodiment described with regard to FIG. 2 discloses that the microelectronic device 202 is attached to the microelectronic interposer 204 prior to attaching the microelectronic device 202 and the microelectronic interposer 204 to the microelectronic substrate 230, it is understood that the microelectronic device 202 may be attached to the microelectronic substrate 230 followed by the attachment of the microelectronic interposer 204 to the microelectronic device 202 and the microelectronic substrate 230.

In the embodiment illustrated in FIG. 2, the microelectronic device 202 may be a low power microelectronic device (e.g. a memory controller hub, a input/output controller hub, a memory device, silicon-on-chip device, a logic device, a graphics device, and the like), such that no heat dissipation devices are required, as will be understood to those skilled in the art.

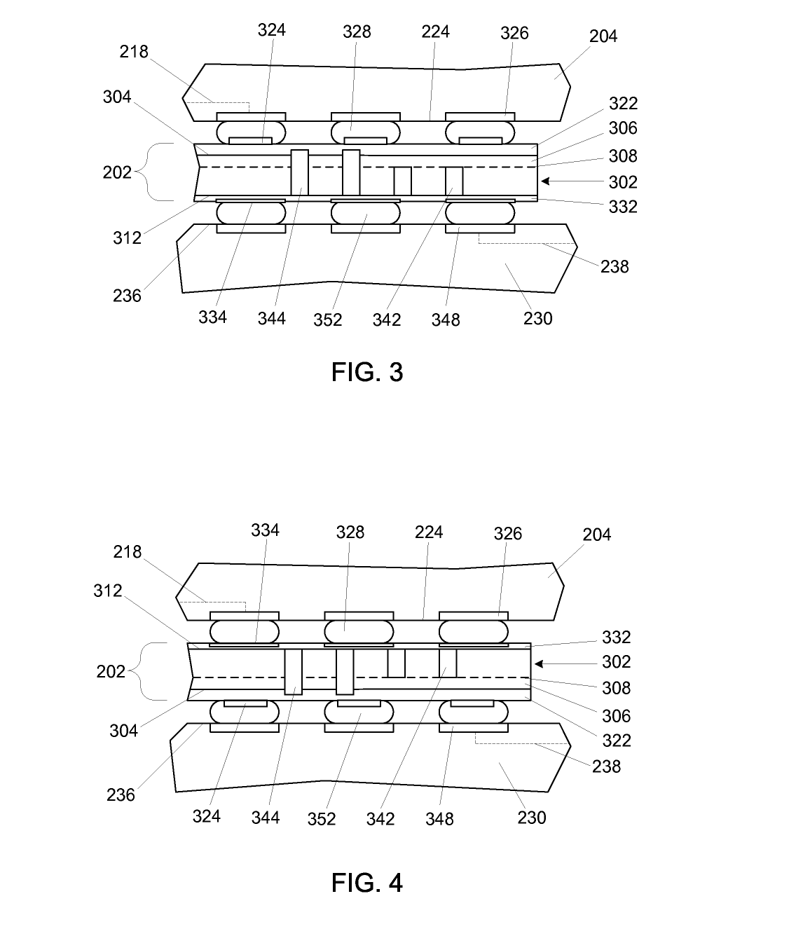

As discussed in regard to FIG. 2, the microelectronic device 202 may be electrically coupled to both the microelectronic interposer 204 and the microelectronic substrate 230. In one embodiment of the present description as illustrated in FIG. 3, the microelectronic device 202 may comprise a semiconducting substrate 302, such as a silicon, silicon-on-insulator, gallium arsenide, silicon-germanium, or the like, having an active surface 304, which has integrated circuitry 306 formed therein and/or thereon (illustrated as an area between the semiconducting substrate active surface 304 and dashed line 308), and an opposing back surface 312. An interconnection layer 322 may be formed on the semiconducting substrate active surface 304. The semiconducting substrate active surface interconnection layer 322 may form electrical connections between bond posts 324, such as copper posts, formed on the semiconducting substrate active surface interconnection layer 322 and the integrated circuitry 306, and may be made of alternating dielectric layers and conductive trace layers connected with conductive vias extending through the dielectric layers (not shown), as will be understood by those skilled in the art.

The microelectronic device active surface bond posts 324 may be electrically attached to device bond pads 326 on the microelectronic interposer land side surface 224 with device-to-interposer interconnects 328, such as with the illustrated microball interconnects, which may extend therebetween. The microelectronic interposer device bond pads 326 may be in electrical communication with the microelectronic interposer conductive routes 218.

As further illustrated in FIG. 3, an interconnection layer 332 may be formed on the semiconducting substrate back surface 312. The semiconducting substrate back surface interconnection layer 332 may form electrical connections between bonds pads 334 formed in or on the semiconducting substrate back surface interconnection layer 332 and the integrated circuitry 306 through at least one through-silicon via extending though the semiconducting substrate 302 from the semiconducting substrate back surface 312 to either the integrated circuitry 306 (illustrated as through-silicon vias 342) and/or to semiconducting substrate active surface interconnection layer 322 (illustrated as through-silicon vias 344). The semiconducting substrate back surface interconnection layer 332 may be made of alternating dielectric layers and conductive trace layers connected with conductive vias extending through the dielectric layers (not shown), as will be understood by those skilled in the art. The process for forming through-silicon vias 342/344 is well known in the art.

The microelectronic device back surface bond pads 334 may be electrically attached to device bond pads 348 on the microelectronic substrate first surface 236 with device-to-substrate interconnects 352, such as with the illustrated solder grid array interconnects, which may extend therebetween. The microelectronic substrate device bond pads 348 may be in electrical communication with the microelectronic substrate conductive routes 238.

Although the embodiment of FIG. 3 illustrates the semiconducting substrate active surface 304 facing the microelectronic interposer land side surface 224, the orientation may be reversed with the semiconducting substrate active surface 304 facing the microelectronic substrate first surface 236, as illustrated in FIG. 4. In such a configuration, the microelectronic device back surface bond pads 334 would be electrically attached to the microelectronic interposer device bond pads 326 on the microelectronic interposer land side surface 224 with the device-to-interposer interconnects 328, which may extend therebetween, and the microelectronic device active surface bond posts 324 would be electrically attached to the microelectronic substrate device bond pads 348 with device-to-substrate interconnects 352, which may extend therebetween.

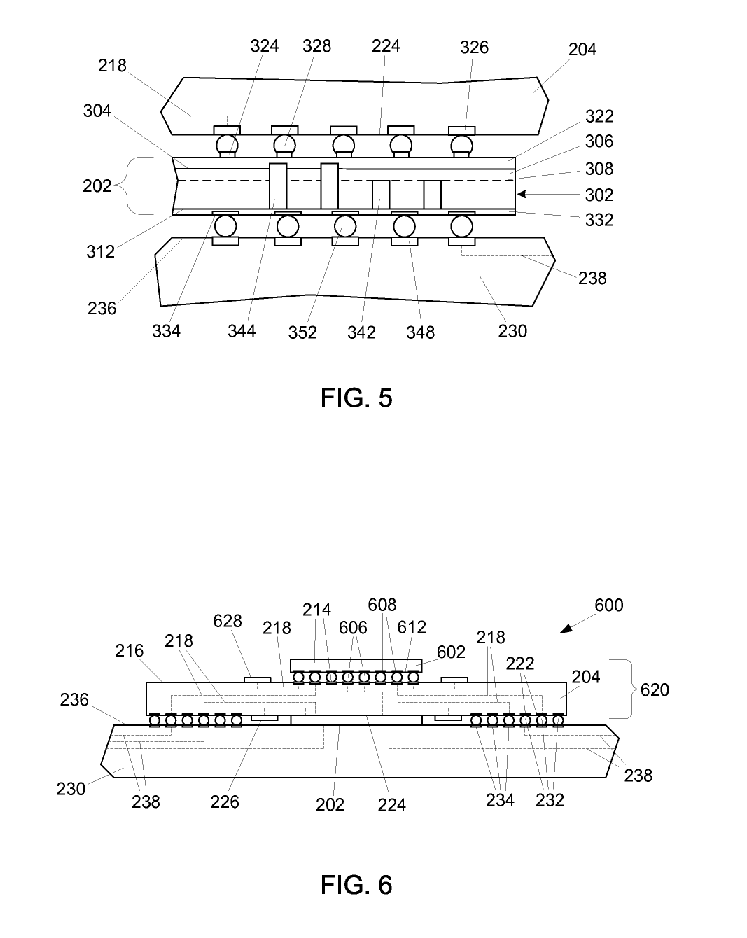

Although the device-to-interposer interconnects 328 and the device-to-substrate interconnects 352 are illustrated as solder grid array interconnects, the subject matter of the present description is not so limited. As illustrated in FIG. 5, the device-to-interposer interconnects 328 and/or the device-to-substrate interconnects 352 may comprise solder ball grid array interconnects.

It is understood that the embodiments of the present description are not limited to a single microelectronic device and may be utilized with a plurality of microelectronic devices. Such an embodiment of a microelectronic structure 600 is illustrated in FIG. 6, wherein an additional microelectronic device 602, such as a microprocessor, a chipset, a controller, a graphics device, a wireless device, a memory device, an application specific integrated circuit, or the like, may be attached to a back side surface 216 of the microelectronic interposer 204 through a plurality of interconnects 606, to form a microelectronic package 620. The additional device-to-interposer interconnects 606 may extend between bond pads 608 on an active surface 612 of the additional microelectronic device 602 and substantially mirror-image bond pads 214 on the microelectronic interposer back side surface 216. The additional microelectronic device bond pads 608 may be in electrical communication with integrated circuitry (not shown) within the additional microelectronic device 602. The microelectronic interposer back surface bond pads 214 may be in electrical communication with microelectronic interposer conductive routes 218 within the microelectronic interposer 204. The microelectronic interposer conductive routes 218 may provide electrical communication routes to the microelectronic interposer land side surface bond pads 222 and to the microelectronic device 202. Furthermore, passive devices 628, such as resistors, capacitors, and inductors, may be attached to the microelectronic interposer back side surface 216 and in electrical communication with the additional microelectronic device 602 through respective microelectronic interposer conductive routes 218.

The embodiment illustrated in FIG. 6 may be advantageous when the additional microelectronic device 602 may be a high power microelectronic device, such as a microprocessor, which may need a heat dissipation device (not shown) attached thereto, and wherein the microelectronic device 202 may be a low power device, such as a memory controller hub, a input/output controller hub, a memory device, and the like, which does not need a heat dissipation device (not shown). Additionally, the close proximity of the microelectronic device 202 and the additional microelectronic device 602 on opposing sides of the microelectronic interposer 204 may increase the input/output speed therebetween.

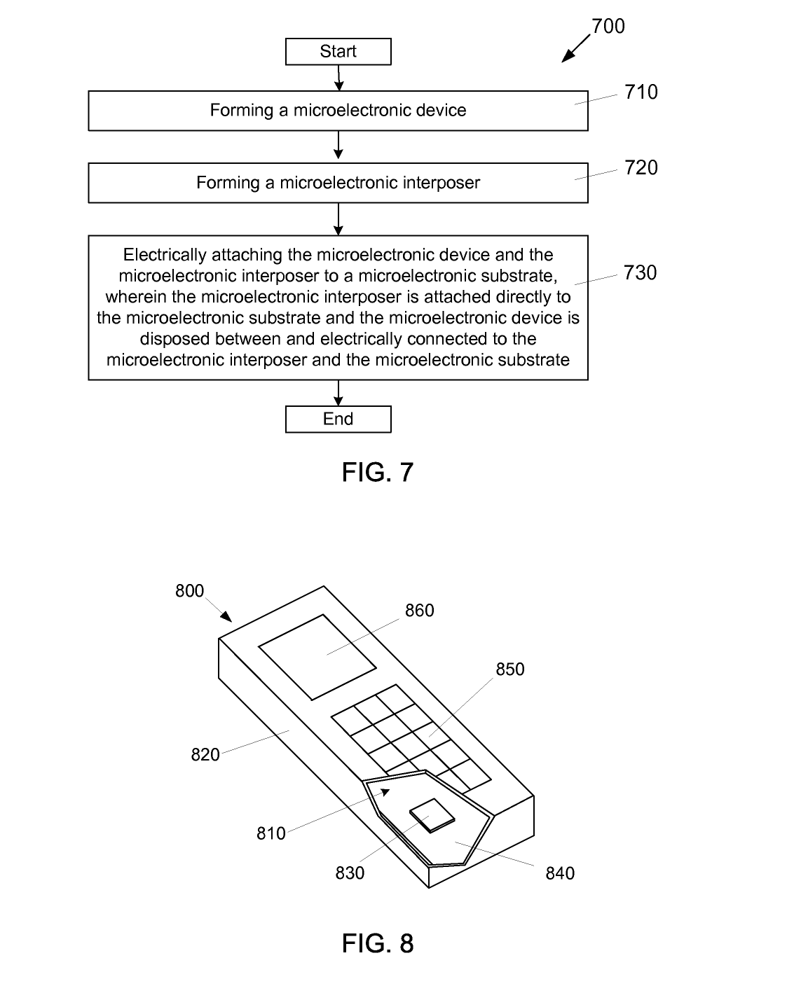

An embodiment of one process of fabricating a microelectronic structure of the present description is illustrated in a flow diagram 700 of FIG. 7. As defined in block 710, a microelectronic device may be formed. As defined in block 720, a microelectronic interposer may be formed. The microelectronic device and the microelectronic interposer may be electrically attached to a microelectronic substrate, wherein the microelectronic interposer is attached directly to the microelectronic substrate and the microelectronic device is disposed between and electrically connected to the microelectronic interposer and the microelectronic substrate, as defined in block 730.

FIG. 8 illustrates an embodiment of a electronic system/device 800, such as a portable computer, a desktop computer, a mobile telephone, a digital camera, a digital music player, a web tablet/pad device, a personal digital assistant, a pager, an instant messaging device, or other devices. The electronic system/device 800 may be adapted to transmit and/or receive information wirelessly, such as through a wireless local area network (WLAN) system, a wireless personal area network (WPAN) system, and/or a cellular network. The electronic system/device 800 may include a microelectronic structure 810 (such as the microelectronic structures 200 and 600 in FIGS. 2-6) within a housing 820. As with the embodiments of the present application, the microelectronic structure 810 may includes a microelectronic substrate 840 (see element 230 of FIGS. 2-6) therein and a microelectronic package 830 including a microelectronic interposer (see element 204 of FIGS. 2-6) having at least one microelectronic device (see element 202 of FIGS. 2-6) position between and electrically attached to the microelectronic interposer (see element 204 of FIGS. 2-6) and the microelectronic substrate 840, wherein the microelectronic package 830 is electrically attached to the microelectronic substrate 810, as disclosed. The microelectronic substrate 810 may be attached to various peripheral devices including an input device 850, such as keypad, and a display device 860, such an LCD display. It is understood that the display device 860 may also function as the input device, if the display device 860 is touch sensitive.

It is understood that the subject matter of the present description is not necessarily limited to specific applications illustrated in FIGS. 1-8. The subject matter may be applied to other microelectronic device fabrication applications, as will be understood to those skilled in the art.

Having thus described in detail embodiments of the present invention, it is understood that the invention defined by the appended claims is not to be limited by particular details set forth in the above description, as many apparent variations thereof are possible without departing from the spirit or scope thereof.

1. A microelectronic structure, comprising:
at least one microelectronic device;
a microelectronic interposer; and
a microelectronic substrate, wherein the microelectronic interposer is electrically attached to the microelectronic substrate with at least one interconnect extending between at least one bond pad on the microelectronic interposer and at least one bond pad on the microelectronic substrate, and the microelectronic device is disposed between and electrically connected to the microelectronic interposer and the microelectronic substrate.

2. The microelectronic structure of claim 1, wherein the at least one microelectronic device includes at least one through-silicon via electrically connected to one of the microelectronic interposer and the microelectronic substrate.

3. The microelectronic structure of claim 1, wherein the at least one microelectronic device is electrically connected to at least one of the microelectronic interposer and the microelectronic substrate with solder grid array interconnects.

4. The microelectronic structure of claim 1, wherein the at least one microelectronic device is electrically connected to at least one of the microelectronic interposer and the microelectronic substrate with ball grid array interconnects.

5. The microelectronic structure of claim 1, wherein the microelectronic interposer includes a land surface and a back surface, wherein the land surface is electrically connected to the at least one microelectronic device and the microelectronic substrate, and wherein at least one additional microelectronic device is electrically connected to the microelectronic interposer back surface.

6. The microelectronic structure of claim 1, wherein the microelectronic interposer includes a land surface and a back surface, wherein the land surface is electrically connected to the at least one microelectronic device and the microelectronic substrate, and wherein at least one passive microelectronic device is electrically connected to the microelectronic interposer land surface.

7. The microelectronic structure of claim 1, further including an underfill material disposed between the microelectronic interposer and the microelectronic substrate.

8. A process of fabricating a microelectronic structure, comprising:
forming at least one microelectronic device;
forming a microelectronic interposer; and
electrically attaching the at least one microelectronic device and the microelectronic interposer to a microelectronic substrate, wherein the microelectronic interposer is attached directly to the microelectronic substrate with at least one interconnect extending between at least one bond pad on the microelectronic interposer and at least one bond pad on the microelectronic substrate, and the microelectronic device is disposed between and electrically connected to the microelectronic interposer and the microelectronic substrate.

9. The process of fabricating the microelectronic structure of claim 8, wherein forming the at least one microelectronic device includes forming at least one through-silicon via therein and further comprising electrically connecting the at least one through-silicon via to one of the microelectronic interposer and the microelectronic substrate.

10. The process of fabricating the microelectronic structure of claim 8, wherein electrically connecting the at least one microelectronic device to one of the microelectronic interposer and the microelectronic substrate comprises electrically connecting the at least one microelectronic device to at least one of the microelectronic interposer and the microelectronic substrate with solder grid array interconnects.

11. The process of fabricating the microelectronic structure of claim 8, wherein electrically connecting the at least one microelectronic device to one of the microelectronic interposer and the microelectronic substrate comprises electrically connecting the at least one microelectronic device to at least one of the microelectronic interposer and the microelectronic substrate with ball grid array interconnects.

12. The process of fabricating the microelectronic structure of claim 8, wherein forming the microelectronic interposer comprises forming the microelectronic interposer with a land surface and a back surface, further comprising electrically connecting the land surface to the at least one microelectronic device and the microelectronic substrate, and further comprising electrically connecting at least one additional microelectronic device to the microelectronic interposer back surface.

13. The process of fabricating the microelectronic structure of claim 8, wherein forming the microelectronic interposer comprises forming the microelectronic interposer with a land surface and a back surface, further comprising electrically connecting the land surface to the at least one microelectronic device and the microelectronic substrate, and further comprising electrically connecting at least one passive microelectronic device to the microelectronic interposer land surface.

14. The process of fabricating the microelectronic structure of claim 8, further including disposing an underfill material between the microelectronic interposer and the microelectronic substrate.

15. A microelectronic system, comprising:
a housing; and
a microelectronic structure disposed within the housing, comprising:
at least one microelectronic device;
a microelectronic interposer; and
a microelectronic substrate, wherein the microelectronic interposer is attached directly to the microelectronic substrate with at least one interconnect extending between at least one bond pad on the microelectronic interposer and at least one bond pad on the microelectronic substrate, and the microelectronic device is disposed between and electrically connected to the microelectronic interposer and the microelectronic substrate.

16. The microelectronic system of claim 15, wherein the at least one microelectronic device includes at least one through-silicon via electrically connected to one of the microelectronic interposer and the microelectronic substrate.

17. The microelectronic system of claim 15, wherein the at least one microelectronic device is electrically connected to at least one of the microelectronic interposer and the microelectronic substrate with solder grid array interconnects.

18. The microelectronic system of claim 15, wherein the at least one microelectronic device is electrically connected to at least one of the microelectronic interposer and the microelectronic substrate with ball grid array interconnects.

19. The microelectronic system of claim 15, wherein the microelectronic interposer includes a land surface and a back surface, wherein the land surface is electrically connected to the at least one microelectronic device and the microelectronic substrate, and wherein at least one additional microelectronic device is electrically connected to the microelectronic interposer back surface.

20. The microelectronic system of claim 15, wherein the microelectronic interposer includes a land surface and a back surface, wherein the land surface is electrically connected to the at least one microelectronic device and the microelectronic substrate, and wherein at least one passive microelectronic device is electrically connected to the microelectronic interposer land surface.

21. The microelectronic system of claim 15, further including an underfill material disposed between the microelectronic interposer and the microelectronic substrate.
